(19) United States
(12) Patent Application Publication
(10) Pub. No.: US 2025/0185217 A1
(43) Pub. Date: Jun. 5, 2025

(54) HEAT DISSIPATION CONTROL METHOD AND APPARATUS BASED ON COOLING TOWER, DEVICE, MEDIUM, AND PRODUCT

(71) Applicant: BITMAIN TECHNOLOGIES INC., Beijing (CN)

(72) Inventors: Tianhao LI, Beijing (CN); Fengjie Li, Beijing (CN); Wenkai Cui, Beijing (CN); Hangkong Hu, Beijing (CN); Xiaoxiong Zhang, Beijing (CN); Hongshan Zhu, Beijing (CN); Shaoming Huang, Beijing (CN)

(21) Appl. No.: 18/968,744

(22) Filed: Dec. 4, 2024

(30) Foreign Application Priority Data
Dec. 5, 2023 (CN) 202311656844.7

(51) Int. Cl. H05K 7/20

(52) U.S. Cl. CPC H05K 7/20781; H05K 7/20218; H05K 7/2039

(57) ABSTRACT

The present application provides a heat dissipation control method based on a cooling tower, including: in response to a heat dissipation control request, obtaining a cooling tower identifier in the heat dissipation control request, and collecting target heat dissipation information of a cooling tower corresponding to the cooling tower identifier; if it is detected that the target heat dissipation information meets a dry-cooling heat dissipation requirement, controlling a dry-cooling heat dissipation system to operate; if it is detected that the target heat dissipation information meets a wet-cooling heat dissipation requirement, controlling a wet-cooling heat dissipation system to operate; if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously.

### CROSS-REFERENCE TO RELATED APPLICATIONS

This application claims priority to Chinese Patent Application No. 202311656844.7, filed on Dec. 5, 2023, which is hereby incorporated herein by reference in its entirety.

### TECHNICAL FIELD

The present application relates to Internet of Things and computer technologies and, in particular, to a heat dissipation control method and apparatus based on a cooling tower, a device, a medium, and a product.

### BACKGROUND

A cooling tower is a device used to cool a machine in a server cluster. The cooling tower can include a dry-cooling heat dissipation mode and a wet-cooling heat dissipation mode. The dry-cooling heat dissipation means that the heat dissipation fan of the cooling tower is started and the air inside the tower is discharged through the heat dissipation fan, air circulation inside the tower is generated to complete the cooling of the temperature inside the tower. The wet-cooling heat dissipation mode achieves the cooling of the temperature inside the tower through spraying water onto the heat dissipation coil, and through the water temperature scattered onto the heat dissipation coil.

However, at present, only dry-cooling heat dissipation or wet-cooling heat dissipation can be fixedly selected, and the cooling mode is relatively single, resulting in a low cooling effect of the cooling tower.

### SUMMARY

The present application provides a heat dissipation control method and apparatus based on a cooling tower, a device, a medium, and a product, so as to address the problem that only dry-cooling heat dissipation or wet-cooling heat dissipation can be fixedly selected for the cooling tower, and the cooling mode is relatively single, resulting in a low cooling effect of the cooling tower.

On the one hand, the present application provides a heat dissipation control method based on a cooling tower, the cooling tower includes a wet-cooling heat dissipation system and a dry-cooling heat dissipation system; and the method includes:
in response to a heat dissipation control request, obtaining a cooling tower identifier in the heat dissipation control request, and collecting target heat dissipation information of a cooling tower corresponding to the cooling tower identifier;
if it is detected that the target heat dissipation information meets a dry-cooling heat dissipation requirement, controlling the dry-cooling heat dissipation system to operate, so as to adopt a dry-cooling heat dissipation mode for heat dissipation;
if it is detected that the target heat dissipation information meets a wet-cooling heat dissipation requirement, controlling the wet-cooling heat dissipation system to operate, so as to adopt a wet-cooling heat dissipation mode for heat dissipation;
if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

On the other hand, the present application provides a heat dissipation control apparatus based on a cooling tower, the cooling tower includes a wet-cooling heat dissipation system and a dry-cooling heat dissipation system; and the apparatus includes:
an information collection unit, configured to collect target heat dissipation information of the cooling tower in response to a heat dissipation control request of the cooling tower;
a dry-cooling heat dissipation unit, configured to, if it is detected that the target heat dissipation information meets a dry-cooling heat dissipation requirement, control the dry-cooling heat dissipation system to operate, so as to adopt a dry-cooling heat dissipation mode for heat dissipation;
a wet-cooling heat dissipation unit, configured to, if it is detected that the target heat dissipation information meets a wet-cooling heat dissipation requirement, control the wet-cooling heat dissipation system to operate, so as to adopt a wet-cooling heat dissipation mode for heat dissipation;
a joint heat dissipation unit, if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

On the other hand, the present application provides an electronic device, including:
a processor, and a memory connected in communication with the processor;
where the memory stores computer execution instructions;
the processor executes the computer execution instructions stored in the memory to implement the method as described in the first aspect.

On the other hand, the present application provides a computer-readable storage medium, storing computer execution instructions which, when executed by a processor, are used to implement the method as described in the first aspect.

On the other hand, the present application provides a computer program product, including a computer program which, when executed by a processor, implements the method as described in the first aspect.

In the technical solution provided in the present application, a cooling tower identifier can be set for each cooling tower, and the mode control of the corresponding cooling tower can be achieved through the cooling tower identifier. When controlling the mode of a single cooling tower, the target heat dissipation information of the cooling tower can be collected, and the actual heat dissipation requirement of the cooling tower can be detected through the target heat dissipation information, so that the cooling tower can operate in a cooling mode corresponding to the actual heat dissipation requirement. That is, when the target heat dissipation information meets the dry-cooling heat dissipation requirement, the dry-cooling heat dissipation mode is used; when the target heat dissipation information meets the wet-cooling heat dissipation requirement, the wet-cooling heat dissipation mode is used; in the case where neither the dry-cooling heat dissipation requirement nor the wet-cooling heat dissipation is met, both the dry-cooling and wet-cooling heat dissipation modes are used; achieving the effect of selecting the corresponding heat dissipation mode according to the actual heat dissipation requirement of the cooling tower. And then, ensuring the heat dissipation effect of the cooling tower while making the heat dissipation process more stable, avoiding phenomena such as excessive cooling or insufficient cooling, and improving the operating effect of the cooling tower.

### BRIEF DESCRIPTION OF DRAWINGS

The accompanying drawings herein which are incorporated into and form a part of the specification, illustrate embodiments in accordance with the present invention, and are used in conjunction with the specification to explain the principles of the present invention.

FIG. 1 is a schematic diagram of a cooling tower provided in an embodiment of the present disclosure.

FIG. 2 is a schematic diagram of an application of a heat dissipation control system based on a cooling tower provided in an embodiment of the present disclosure.

FIG. 3 is a flowchart of a heat dissipation control method based on a cooling tower provided in an embodiment of the present disclosure.

FIG. 4 is an exemplary diagram of a detection of a dry-cooling heat dissipation mode provided in an embodiment of the present disclosure.

FIG. 5 is an exemplary diagram of a detection of a wet-cooling heat dissipation mode provided in an embodiment of the present disclosure.

FIG. 6 is a flowchart of another embodiment of a heat dissipation control method based on a cooling tower provided in an embodiment of the present disclosure.

FIG. 7 is a flowchart of another embodiment of a heat dissipation control method based on a cooling tower provided in an embodiment of the present disclosure.

FIG. 8 is a schematic structural diagram of an embodiment of a heat dissipation control apparatus based on a cooling tower provided in an embodiment of the present disclosure.

FIG. 9 is a block diagram of an electronic device used to implement a heat dissipation control method based on a cooling tower provided in an embodiment of the present disclosure.

Through the above accompanying drawings, definite embodiments of the present application have been shown, and more detailed descriptions will be provided in the following. These accompanying drawings and textual descriptions are not intended to limit the scope of concepts of the present application in any way, but rather to illustrate the concepts of the present application for those skilled in the art by referring to particular embodiments.

### DESCRIPTION OF EMBODIMENTS

Exemplary embodiments will be described in detail herein, examples of which are represented in the accompanying drawings. When the following description relates to the accompanying drawings, unless otherwise indicated, the same numbers in different accompanying drawings indicate the same or similar elements. The implementations described in the following exemplary embodiments do not represent all implementations consistent with the present application. In contrary, they are only examples of apparatuses and methods consistent with some aspects of the present application as described in the appended claims.

The technical solution of the present disclosure provides a heat dissipation control method and apparatus based on a cooling tower, a device, a medium, and a product. Through collecting the target heat dissipation information of the cooling tower, whether to select the dry-cooling heat dissipation mode or wet-cooling heat dissipation mode, or the joint operation of the dry-cooling heat dissipation mod and the wet-cooling heat dissipation mode is determined through the target heat dissipation information, so that the selection of the heat dissipation mode of the cooling tower is related to the cooling effect of the cooling tower itself, rather than the use of a single mode, and to improve the cooling effect of the cooling tower.

In related technologies, the cooling tower is a device used to cool machines such as servers. The cooling tower generally includes a dry-cooling heat dissipation system and a wet-cooling heat dissipation system. The dry-cooling heat dissipation system means that the circulation of air in the tower is achieved through the rotation of the heat dissipation fan, in turn achieving the cooling of the air inside the tower. The wet-cooling heat dissipation system means that a spray pipe is set up at the top of the tower, a heat dissipation coil is set up below the spray pipe, the spray pipe spray water onto the heat dissipation coil, and there is a water collecting tray below the heat dissipation coil, and the water in the water collecting tray is then collected again through the heat dissipation coil; so that achieving the cooling of the water circulation. At present, the cooling tower generally operate using the dry-cooling heat dissipation system or the wet-cooling heat dissipation system, this operation manner is relatively single, which leads to the cooling tower is prone to insufficient or excessive cooling, resulting in lower operational efficiency of the cooling tower.

In order to solve the above problem, in the technical solution of the present disclosure, a cooling tower identifier can be set for each cooling tower, and the mode control of the corresponding cooling tower can be achieved through the cooling tower identifier. When controlling the mode of a single cooling tower, the target heat dissipation information of the cooling tower can be collected, and the actual heat dissipation requirement of the cooling tower can be detected through the target heat dissipation information, so that the cooling tower can operate in a cooling mode corresponding to the actual heat dissipation requirement, ensuring the heat dissipation effect of the cooling tower while making the heat dissipation process more stable, avoiding phenomena such as excessive cooling or insufficient cooling, and improving the operating effect of the cooling tower.

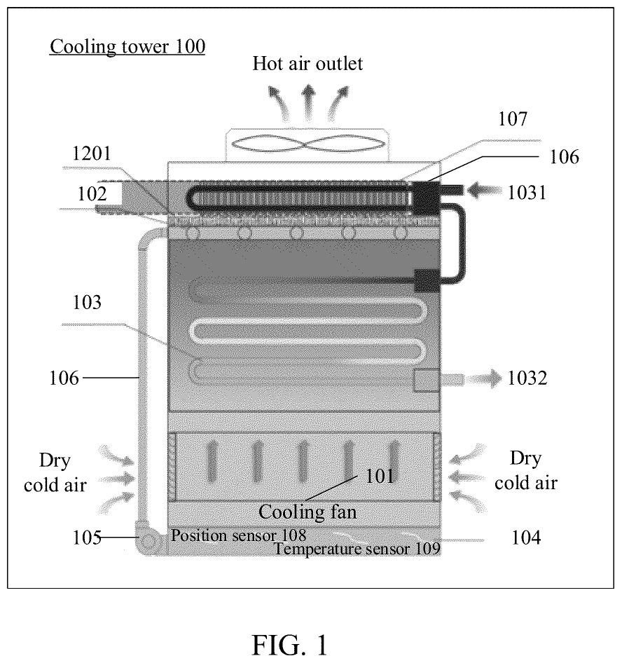

In order to facilitate the understanding of the technical solution of the present disclosure, FIG. 1 illustrates a schematic diagram of a cooling tower provided in an embodiment of the present disclosure. Referring to FIG. 1, the cooling tower 100 can include a dry-cooling heat dissipation system and a wet-cooling heat dissipation system. The dry-cooling heat dissipation system can include a cooling fan (not shown in the figure, only the position 101 of the cooling fan is shown). The wet-cooling heat dissipation system can include: a spray pipe 102, a heat dissipation coil 103, a water collection tank 104, and a circulating water pump 105 connecting the water collection tank 104 and the spray pipe 102, the spray pipe 102 can also include a water collector 1201, the water collector 1201 is used to collect water into the spray pipe.

The cooling fan 101 is located directly above the water collection tank 104, and a perpendicular line perpendicular to the plane of the water collection tank can be determined with the center of the water collection tank as an endpoint, and the center point of the cooling fan is located on this perpendicular line. A hollow wall is provided on the side wall above the cooling fan 101 of the cooling tower 100, which allows air circulation. The spray pipe 102 is located above the heat dissipation coil 103. The heat dissipation coil 103 includes a cooling liquid inlet 1031 and a cooling liquid outlet 1032. Cooling liquid being circulating and flowing is provided inside the heat dissipation coil 103, and a temperature sensor 106 is provided at the cooling liquid inlet of the heat dissipation coil for collecting a liquid supply temperature. A side of the water collection tank 104 is connected to the circulating water pump 105, the circulating water pump 105 is connected to a vertical pipe 106, and the vertical pipe 106 is connected to the spray pipe 102.

In addition, a pre-cooled finned tube 107 can also be provided on the heat dissipation coil 103. A position sensor 108 can also be provided on the water collection tank 104 for collecting a height of liquid in the water collection tank 104 and obtaining a liquid height. The position sensor 108 can be provided on the side or top of the water collection tank, and the position of the position sensor is not overly limited herein. A temperature sensor 109 can also be provided at the bottom of the water collection tank 104 for collecting a temperature of liquid inside the water collection tank 104.

The heat dissipation mode of the cooling tower includes a dry-cooling heat dissipation mode and a wet-cooling heat dissipation mode.

The wet-cooling heat dissipation mode means that the water in the water collection tank extracted by the circulating water pump is controlled, the water extracted by the circulating water pump enters the spray pipe through the vertical pipe, and the water is sprayed to the heat dissipation coil through the spray water pipe to reduce the temperature of the cooling liquid inside the heat dissipation coil, and the water collection tank is used to collect the sprayed water;

The dry-cooling heat dissipation mode means that the heat dissipation fan is started to extract the outside air into the cooling tower, and after the air passing through the heat dissipation coil, the temperature of the cooling liquid inside the heat dissipation coil is reduced, and finally allowing the air to be discharged from the top of the cooling tower, achieving the air circulation inside the cooling tower.

The heat dissipation control method based on the cooling tower provided in the present application aims to solve the above-mentioned technical problem in the related art.

The technical solution of the present application and how the technical solution of the present application solve the above technical problem are described in detail below through specific embodiments. These following specific embodiments can be combined with each other, and the same or similar concepts or processes may not be repeated in certain embodiments. Embodiments of the present application will be described below in conjunction with the accompanying drawings.

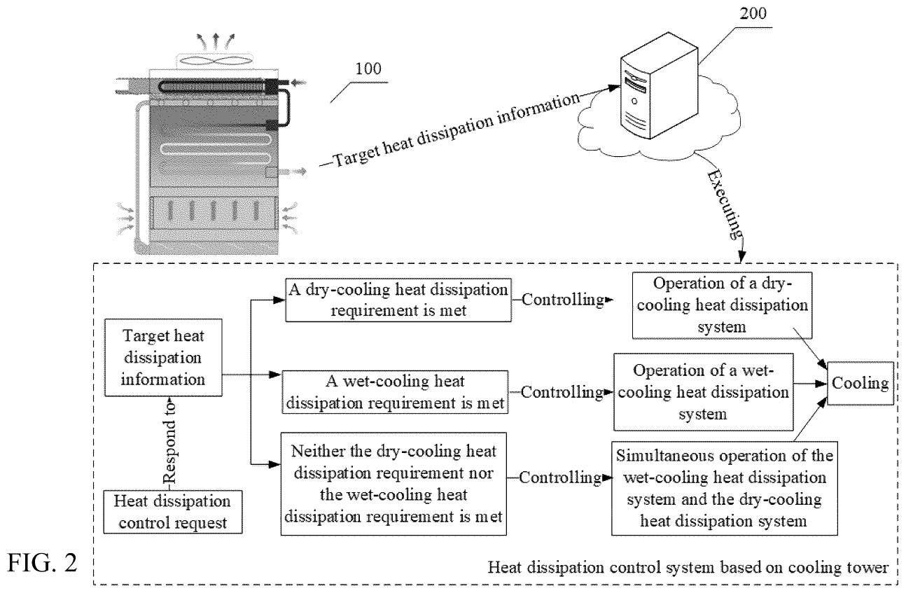

As shown in FIG. 2, it is a schematic diagram of an application of a heat dissipation control system based on a cooling tower provided in an embodiment of the present disclosure. Referring to the system shown in FIG. 2, it can include the cooling tower 100 as shown in FIG. 1 and an electronic device 200 that is in communication with various sensors of the cooling tower 100. The electronic device 22 can collect target heat dissipation information of the cooling tower through sensors inside the cooling tower 21. In practical applications, the cooling tower can include multiple ones, and FIG. 2 shows the case of one cooling tower.

As shown in FIG. 2, in response to a heat dissipation control request, the electronic device 22 can obtain a cooling tower identifier corresponding to the heat dissipation control request, and collect target heat dissipation information of a cooling tower corresponding to the cooling tower identifier. The heat dissipation mode of the cooling tower can be confirmed on the basis of the target heat dissipation information.

Furthermore, if it is detected that the target heat dissipation information meets a dry-cooling heat dissipation requirement, controlling a dry-cooling heat dissipation system to operate, so as to adopt a dry-cooling heat dissipation mode for heat dissipation; if it is detected that the target heat dissipation information meets a wet-cooling heat dissipation requirement, controlling a wet-cooling heat dissipation system to operate, so as to adopt a wet-cooling heat dissipation mode for heat dissipation; if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

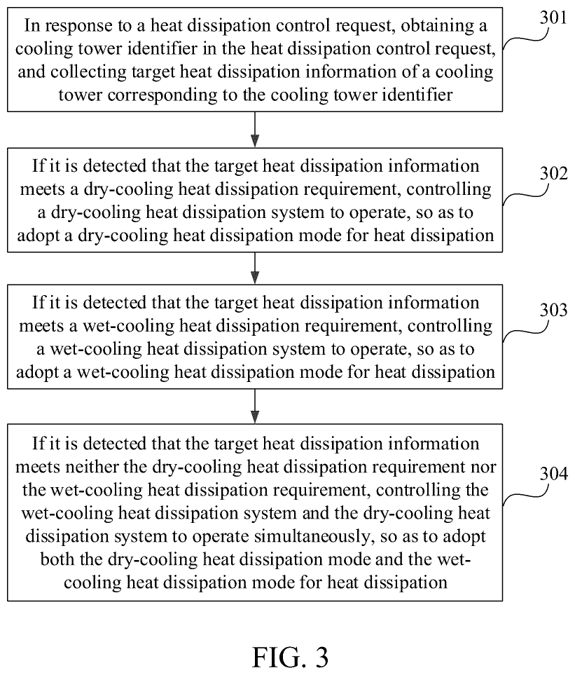

FIG. 3 is a flowchart of a heat dissipation control method based on a cooling tower provided in an embodiment of the present disclosure. The method can be configured as a heat dissipation control apparatus based on a cooling tower, which can be located in an electronic device. The electronic device can be a server or any type of electronic devices corresponding to the cooling tower, the server may for example be a computer or a cloud server. The heat dissipation control method based on the cooling tower shown in FIG. 3 can include the following steps.

Step 301, in response to a heat dissipation control request, obtaining a cooling tower identifier in the heat dissipation control request, and collecting target heat dissipation information of a cooling tower corresponding to the cooling tower identifier.

In an implementation, the heat dissipation control request can include a heat dissipation control request triggered by a user, or initiating a heat dissipation control request of the cooling tower when the cooling tower is started. The heat dissipation control request can refer to a request generated based on a cooling tower identifier of any cooling tower. The heat dissipation control request can indicate that performing heat dissipation control on the cooling tower with the cooling tower identifier.

The obtaining the cooling tower identifier in the heat dissipation control request can include: parsing the heat dissipation control request, the heat dissipation control request may be a URL request, and reading the cooling tower identifier from the heat dissipation control request.

In an implementation, the collecting the target heat dissipation information of the cooling tower corresponding to the cooling tower identifier can include: generating an information collection instruction based on an information collection strategy, and sending the information collection instruction to each sensor in the cooling tower, so as to receive the target heat dissipation information uploaded by each sensor in accordance with the information collection strategy.

The target heat dissipation information can refer to a value of a heat dissipation parameter collected according to the information collection strategy. The heat dissipation parameter can include at least one of the following: an ambient temperature outside a tower, a liquid supply temperature inside a tower, a water collecting tray temperature, and a liquid height of the cooling tower.

The ambient temperature outside the tower can be collected through a temperature sensor provided outside the cooling tower. The liquid supply temperature inside the tower can be collected through a temperature sensor provided at a liquid supply port on the cooling coil. The water collecting tray temperature can be collected through a temperature sensor provided at a bottom or at a height threshold of the water collecting tray. The liquid height is detected through the position sensor provided on the water collecting tray.

Step 302, if it is detected that the target heat dissipation information meets a dry-cooling heat dissipation requirement, controlling a dry-cooling heat dissipation system to operate, so as to adopt a dry-cooling heat dissipation mode for heat dissipation.

In an implementation, if it is detected that a heat dissipation requirement indicated by the target heat dissipation information is low; determining that the dry-cooling heat dissipation requirement is met. The controlling the dry-cooling heat dissipation system to operate can include: starting a cooling fan of the dry-cooling heat dissipation system, and controlling the cooling fan to move at a certain operating frequency.

Step 303, if it is detected that the target heat dissipation information meets a wet-cooling heat dissipation requirement, controlling a wet-cooling heat dissipation system to operate, so as to adopt a wet-cooling heat dissipation mode for heat dissipation.

In an implementation, the detecting that the target heat dissipation information meets the wet-cooling heat dissipation requirement can include: if it is detected that the heat dissipation requirement of the cooling tower indicated by the target heat dissipation information is high, determining that the cooling tower needs to start the wet-cooling heat dissipation mode, and thus the wet-cooling heat dissipation mode can operate normally.

In an implementation, the controlling the wet-cooling heat dissipation system to operate can include: controlling the spray pipe of the wet-cooling heat dissipation system to start spraying, controlling a cooling liquid inlet of the heat dissipation coil of the wet-cooling heat dissipation system to start inputting liquid into the heat dissipation coil, and outputting liquid from a cooling liquid outlet.

Step 304, if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

In an implementation, the detecting that the target heat dissipation information meets neither the dry-cooling heat dissipation requirement nor the wet-cooling heat dissipation requirement can include: detecting that other situations other than the target heat dissipation information meeting the dry-cooling heat dissipation requirement does not meet the dry-cooling heat dissipation requirement, and detecting that other situations other than the target heat dissipation information meeting the wet-cooling heat dissipation requirement does not meet the wet-cooling heat dissipation requirement.

The controlling the wet-cooling heat dissipation system and the dry-cooling heat dissipation system to operate simultaneously can include: controlling the cooling fan of the dry-cooling heat dissipation system to start, so as to start the dry-cooling heat dissipation system, while simultaneously starting liquid delivery and spraying of the wet-cooling heat dissipation system.

In an implementation, the detecting that the target heat dissipation information meets neither the dry-cooling heat dissipation requirement nor the wet-cooling heat dissipation requirement can include: determining that neither the dry-cooling heat dissipation requirement nor the wet-cooling heat dissipation requirement is met based on at least one of the ambient temperature outside the tower, the liquid supply temperature inside the tower, the water collecting tray temperature, and the liquid height.

Taking the ambient temperature outside the tower as an example, when the ambient temperature outside the tower is less than the first temperature threshold, the dry-cooling heat dissipation requirement is met. When the ambient temperature outside the tower is greater than the third temperature threshold, the wet-cooling heat dissipation requirement is met. The third temperature threshold is greater than the first temperature threshold. When the ambient temperature outside the tower is greater than the first temperature threshold and less than the third temperature threshold, that is, within the range of [first temperature threshold, third temperature threshold], it meets neither the dry-cooling heat dissipation requirement nor the wet-cooling heat dissipation requirement. Of course, the above-mentioned manner is only exemplary, and when the target heat dissipation information meets neither the dry-cooling heat dissipation requirement nor the wet-cooling heat dissipation requirement, a heat dissipation mode that meets a combination of the wet-cooling heat dissipation mode and the dry-cooling heat dissipation mode can be determined.

In the technical solution of the present disclosure, a cooling tower identifier can be set for each cooling tower, and the mode control of the corresponding cooling tower can be achieved through the cooling tower identifier. When controlling the mode of a single cooling tower, the target heat dissipation information of the cooling tower can be collected, and the actual heat dissipation requirement of the cooling tower can be detected through the target heat dissipation information, so that the cooling tower can operate in a cooling mode corresponding to the actual heat dissipation requirement. That is, when the target heat dissipation information meets the dry-cooling heat dissipation requirement, the dry-cooling heat dissipation mode is used; when the target heat dissipation information meets the wet-cooling heat dissipation requirement, the wet-cooling heat dissipation mode is used; in the case where neither the dry-cooling heat dissipation requirement nor the wet-cooling heat dissipation is met, both the dry-cooling and wet-cooling heat dissipation modes are used; achieving the effect of selecting the corresponding heat dissipation mode according to the actual heat dissipation requirement of the cooling tower. And then, ensuring the heat dissipation effect of the cooling tower while making the heat dissipation process more stable, avoiding phenomena such as excessive cooling or insufficient cooling, and improving the operating effect of the cooling tower.

The heat dissipation effect of the wet-cooling heat dissipation system is greater than that of the dry-cooling heat dissipation system.

Further, on the basic of any one of the embodiments described above, the detecting that the target heat dissipation information meets the dry-cooling heat dissipation requirement includes:
in a case where the target heat dissipation information includes an ambient temperature outside a tower, if it is detected that the ambient temperature outside the tower is less than a preset first temperature threshold, determining that the target heat dissipation information meets the dry-cooling heat dissipation requirement; or
in a case where the target heat dissipation information includes a liquid supply temperature, if it is detected that the liquid supply temperature is less than a preset second temperature threshold, determining that the target heat dissipation information meets the dry-cooling heat dissipation requirement, where the liquid supply temperature refers to a temperature of liquid input to a heat dissipation coil of the wet-cooling heat dissipation system; or
in a case where the target heat dissipation information includes a water collecting tray temperature, if it is detected that the water collecting tray temperature is greater than a second temperature threshold, determining that the target heat dissipation information meets the dry-cooling heat dissipation requirement, where the water collecting tray temperature refers to a temperature of liquid in a water collecting tray of the wet-cooling heat dissipation system; or
in a case where the target heat dissipation information includes a liquid supply temperature, calculating a temperature difference obtained by subtracting a preset target temperature from the liquid supply temperature, if it is detected that the temperature difference is greater than a preset temperature difference threshold, determining that the target heat dissipation information meets the dry-cooling heat dissipation requirement; or
in a case where the target heat dissipation information includes a liquid height, if it is detected that the liquid height is less than a preset height threshold (liquid level alarm), determining that the target heat dissipation information meets the dry-cooling heat dissipation requirement, where the liquid height indicates a height of liquid in a water collecting tray of the wet-cooling heat dissipation system.

In an implementation, the first temperature threshold can be a preset temperature threshold, and the second temperature threshold can be a preset temperature threshold. The first temperature threshold is less than the second temperature threshold, for example, the first temperature threshold may be 5 degrees Celsius and the second temperature threshold may be 25 degrees Celsius.

It should be noted that the first temperature threshold, second temperature threshold, third temperature threshold, fourth temperature threshold, etc. in the present disclosure are only used to distinguish temperature thresholds with different values from names, and do not have specific meanings of order or size.

The detecting that the temperature difference between the liquid supply temperature and the preset target temperature is greater than the preset temperature difference threshold can include: calculating the temperature difference between the liquid supply temperature and the preset target temperature, and determining that the temperature difference is greater than the temperature difference threshold. If both the height threshold and the temperature difference threshold meet the dry-cooling heat dissipation mode, determining that the dry-cooling heat dissipation requirement is met.

In an implementation, if it is detected that the water collecting tray temperature is greater than the second temperature threshold, determining that the target heat dissipation information meets the dry-cooling heat dissipation requirement; if it is detected again that the temperature inside the water collecting tray is less than a heating threshold, it indicates that the water temperature inside the water collecting tray is low and there is a risk of icing; thus, determining that the target heat dissipation information meets the wet-cooling heat dissipation requirement, and turning on spraying. The heating threshold can be, for example, a temperature close to a freezing temperature, which is 0 degrees Celsius. The heating threshold can be, for example, 2 degrees Celsius or 1 degrees Celsius.

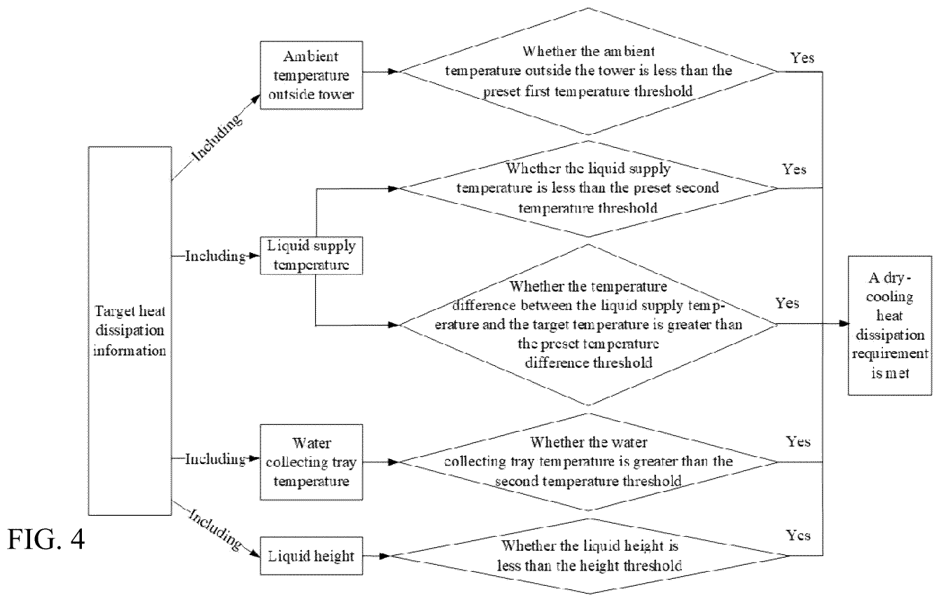

For ease of understanding, FIG. 4 illustrates an example diagram of a detection of a dry-cooling heat dissipation mode. Referring to FIG. 4, the target heat dissipation information can include any one or more of an ambient temperature outside a tower, a liquid supply temperature, a water collecting tray temperature, and a liquid height. When including the ambient temperature outside the tower, it can be determined whether the ambient temperature outside the tower is less than the preset first temperature threshold; if so, it can be determined that the dry-cooling heat dissipation requirement is met. When including the liquid supply temperature, it can be determined whether the liquid supply temperature is less than the second temperature threshold; if so, it can be determined that the dry-cooling heat dissipation requirement is met; in addition, it can also be determined whether the temperature difference between the liquid supply temperature and the target temperature is greater than the preset temperature difference threshold; if so, it can be determined that the dry-cooling heat dissipation requirement is met. When including the water collecting tray temperature, it can be determined whether the water collecting tray temperature is greater than the second temperature threshold; if so, it can be determined that the dry-cooling heat dissipation requirement is met. When including the liquid height, it can be determined whether the liquid height is less than the height threshold; if so, it can be determined that the dry-cooling heat dissipation requirement is met.

In the technical solution of the present disclosure, different information dimensions are set through the target heat dissipation information, such as any one of the ambient temperature, the liquid supply temperature, the water collecting tray temperature, or the liquid height. Furthermore, when the ambient temperature outside the tower is less than the first temperature threshold, the dry-cooling heat dissipation is used to reduce spraying. Or, when the liquid supply temperature is less than the preset second temperature threshold, it indicates that the liquid supply temperature is low and there is no need for excessive cooling, the dry-cooling heat dissipation mode can be used. Or, if the water collecting tray temperature is greater than the second temperature threshold, the temperature in the water collection tank is higher, and the water temperature in the water collecting tray is higher, which greatly reduces the possibility of icing. At this time, there is no need to spray anymore, and the dry-cooling heat dissipation mode can be used to achieve the purpose of saving energy consumption. Or, if it is detected that the temperature difference between the liquid supply temperature and the preset target temperature is greater than the preset temperature difference threshold, the liquid supply temperature is lower, and the dry-cooling heat dissipation mode can be used. Or, if the liquid height is less than the height threshold, it indicates that the water level in the water collecting tray is low; if the wet-cooling heat dissipation is continued to be used, there may be a phenomenon of wet cooling idling. At this point, the wet-cooling heat dissipation can no longer be used, thus, the dry-cooling heat dissipation can be used. Based on the comparison between any of the above dimensions and the corresponding threshold, it is possible to detect whether the target heat dissipation information meets the dry-cooling heat dissipation requirement, and achieving that directly detecting the dry-cooling heat dissipation requirement using the target heat dissipation information, completing the rapid detection and judgment of the dry-cooling heat dissipation mode.

Further, on the basic of any one of the embodiments described above, the detecting that the target heat dissipation information meets the wet-cooling heat dissipation requirement includes:
in a case where the target heat dissipation information includes a liquid height, an ambient temperature outside a tower and a liquid supply temperature, and in a case where the liquid height is greater than or equal to a preset height threshold, if it is detected that the ambient temperature outside the tower is greater than a preset third temperature threshold, and the liquid supply temperature is greater than a fourth temperature threshold, determining that the target heat dissipation information meets the wet-cooling heat dissipation requirement; or
in a case where the target heat dissipation information includes a liquid height and an ambient temperature outside a tower, if it is detected that the liquid height is greater than or equal to a preset height threshold, and the ambient temperature outside the tower is less than a preset first temperature threshold, determining that the target heat dissipation information meets the dry-cooling heat dissipation requirement; or
in a case where the target heat dissipation information includes a liquid height and a water collecting tray temperature, if it is detected that the liquid height is greater than or equal to a preset height threshold, and the water collecting tray temperature is less than a preset first temperature threshold, determining that the target heat dissipation information meets the dry-cooling heat dissipation requirement.

In an implementation, both the third temperature threshold and the fourth temperature threshold can be a preset temperature threshold. In an implementation, the third temperature threshold can be 10 degrees Celsius, and the fourth temperature threshold can be 30 degrees Celsius. The third temperature threshold is greater than the first temperature threshold, and the fourth temperature threshold is greater than the second temperature threshold.

In an implementation, the third temperature threshold can be obtained by presetting. The fourth temperature threshold can be obtained by setting. For example, the third temperature threshold can be set to 10 degrees Celsius, and the fourth temperature threshold can be set to 30 degrees Celsius.

The target heat dissipation information can refer to heat dissipation information collected through the parameter collection strategy. Of course, in the technical solution of the present disclosure, a plurality of parameters such as the ambient temperature outside the tower, the liquid supply temperature inside the tower, the water collecting tray temperature, and the liquid height of the cooling tower can also be collected simultaneously, and the above-mentioned wet-cooling heat dissipation needs are set one by one to achieve the detection of the wet-cooling heat dissipation.

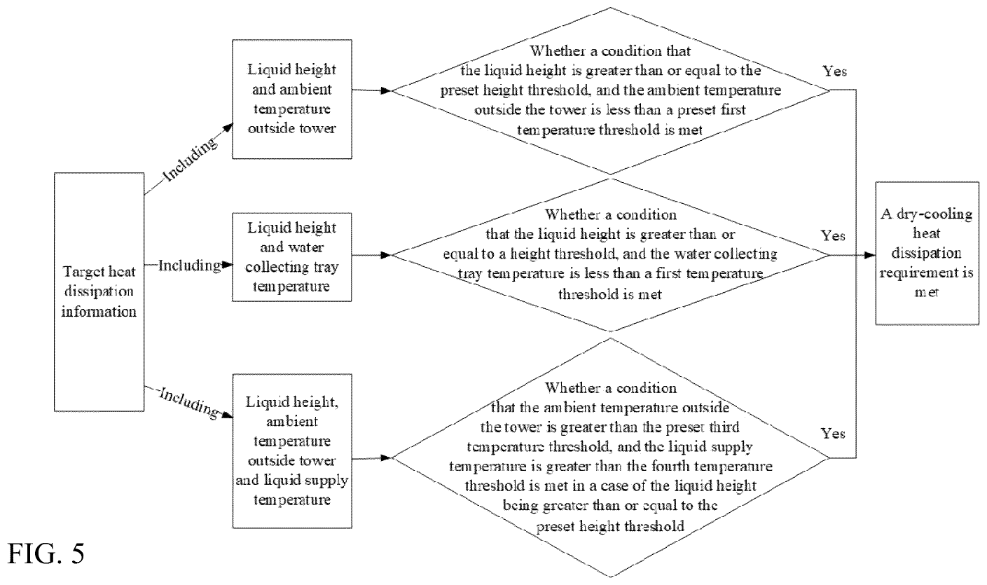

For ease of understanding, FIG. 5 is an example diagram of a detection of a wet-cooling heat dissipation mode. The target heat dissipation information includes more than one of the liquid height, the ambient temperature outside the tower, the liquid supply temperature, and the water collecting tray temperature. In a case where the target heat dissipation information includes the liquid height, the ambient temperature outside the tower and the liquid supply temperature, it can be determined, in a case of the liquid height being greater than or equal to the preset height threshold, whether the ambient temperature outside the tower is greater than the preset third temperature threshold, and the liquid supply temperature is greater than the fourth temperature threshold, if so, it is determined that the wet-cooling heat dissipation requirement is met. In a case where the target heat dissipation information includes a liquid height and an ambient temperature outside a tower, if it is detected that the liquid height is greater than or equal to a preset height threshold, and the ambient temperature outside the tower is less than a preset first temperature threshold, it is determined that the wet-cooling heat dissipation requirement is met. In a case of including a liquid height and an ambient temperature outside a tower, it can be determined whether the liquid height is greater than or equal to a height threshold, and the water collecting tray temperature is less than a first temperature threshold, if so, it is determined that the wet-cooling heat dissipation requirement is met.

In the technical solution of the present disclosure, in a case of the target heat dissipation information including the liquid height, the ambient temperature outside the tower, and the liquid supply temperature, if the liquid height is greater than or equal to the preset height threshold, it indicates that the water in the water collecting tray is sufficient, and wet cooling can be carried out. Furthermore, when the liquid height is greater than or equal to the preset height threshold, and the ambient temperature outside the tower is less than the preset first temperature threshold, it indicates that the ambient temperature of the cooling tower is low, and wet cooling alone can meet the cooling requirement of the server. At this time, the wet-cooling heat dissipation mode can be used. Or, in a case where the water collecting tray temperature is less than the first temperature threshold, it indicates that the temperature of the liquid inside the water collecting tray is low; if the wet-cooling heat dissipation is not started, there is a high possibility that the liquid in the water collecting tray will freeze. In order to ensure the continuous operation of the wet-cooling heat dissipation system, the wet-cooling heat dissipation mode can be adopted when the water collecting tray temperature is low; so as to reduce or avoid liquid freezing inside the water collecting tray through the liquid circulation inside the water collecting tray, so that both heat dissipation modes of the cooling tower can operate normally.

In practical applications, when the external temperature is low; the liquid in the spray pipe and water collecting tray inside the cooling tower needs to be manually emptied to avoid freezing. This control manner is more complex to operate, and the control efficiency of the cooling tower is low. When the water collecting tray temperature or the external ambient temperature is low; and there is no water level warning in the water collecting tray, the wet-cooling heat dissipation mode is adopted, so as to ensure that the wet-cooling system inside the cooling tower is still operating normally, avoiding icing.

Further, on the basic of any one of the embodiments described above, the collecting the target heat dissipation information of the cooling tower includes:
collecting at least one of an ambient temperature outside a tower, a liquid supply temperature inside the tower, a water collecting tray temperature, and a liquid height of the cooling tower in accordance with a preset parameter collection strategy;
determining at least one of the ambient temperature outside the tower, the liquid supply temperature, the water collecting tray temperature, and the liquid height as the target heat dissipation information.

In an implementation, according to the dry-cooling heat dissipation mode and wet-cooling heat dissipation cooling mode supported by the cooling tower, collecting at least one of the following: the ambient temperature outside the tower, the liquid supply temperature inside the tower, the water collecting tray temperature, and the liquid height of the cooling tower.

The parameter collection strategy can be set according to actual analysis needs, which can include one parameter to be collected or a plurality of parameter values to be collected. The parameter collection strategy can include information such as collection frequency, collection time, and collected parameters. According to the parameter collection strategy, at least one parameter of the cooling tower can be collected, such as the ambient temperature outside the tower, the liquid supply temperature, the water collecting tray temperature, and the liquid height.

In the technical solution of the present disclosure, when collecting the target heat dissipation information of the cooling tower, at least one of the ambient temperature outside the tower, the liquid supply temperature, the water collecting tray temperature and liquid height is collected as the target heat dissipation information based on the preset parameter collection strategy, achieving on-demand collection of the target heat dissipation information, and avoiding invalid collection of the target heat dissipation information.

In the technical solution of the present disclosure, a bypass valve can be provided for the heat dissipation coil of the wet-cooling heat dissipation system, and the liquid flow rate of the heat dissipation coil can be controlled through the bypass valve to achieve liquid flow rate control.

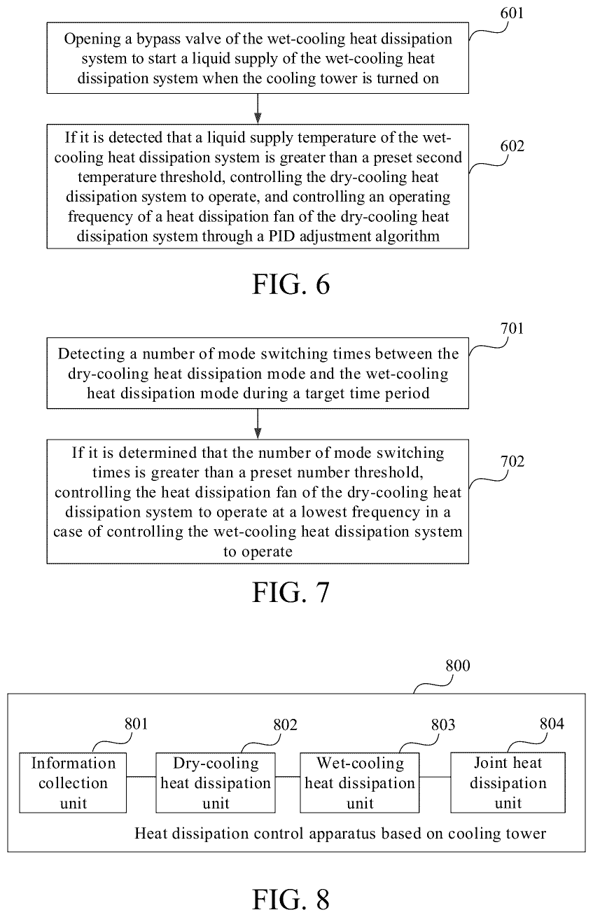

As shown in FIG. 6, it is a flowchart of another embodiment of a heat dissipation control method based on a cooling tower provided in an embodiment of the present disclosure, the difference from the previous embodiment is that it further includes:

Step 601, opening a bypass valve of the wet-cooling heat dissipation system to start a liquid supply of the wet-cooling heat dissipation system when the cooling tower is turned on.

In an implementation, the turning on the cooling tower can include controlling the cooling tower to turn on in response to a turn-on instruction triggered by a user. When the cooling tower is turned on, liquid can be injected into the heat dissipation coil of the cooling tower to allow the liquid inside the heat dissipation coil to flow, achieving heat dissipation inside the tower. The heat dissipation coil can include a cooling liquid inlet and a cooling liquid outlet. The cooling liquid inlet is continuously injected with liquid, while the cooling liquid outlet is continuously discharged with liquid, thereby achieving liquid flow inside the heat dissipation coil to remove heat. The bypass valve can be provided at the cooling liquid inlet of the heat dissipation coil, and the flow rate of the cooling liquid can be controlled through the bypass valve.

Step 602, if it is detected that a liquid supply temperature of the wet-cooling heat dissipation system is greater than a preset second temperature threshold, controlling the dry-cooling heat dissipation system to operate, and controlling an operating frequency of a heat dissipation fan of the dry-cooling heat dissipation system through a PID (Proportional-Integral-Derivative) adjustment algorithm.

In an implementation, the value of the second temperature threshold can refer to the description of the previous embodiments. When the liquid supply temperature is greater than the second temperature threshold, it indicates that the supply liquid temperature is high, and the heat dissipation needs to be initiated. At this time, the dry-cooling heat dissipation system can be started.

The controlling an operating frequency of a heat dissipation fan of the dry-cooling heat dissipation system through a PID adjustment algorithm can include: calculating the operating frequency of the heat dissipation fan of the dry-cooling heat dissipation system through the PID adjustment algorithm, generating an operating instruction of the heat dissipation fan based on the operating frequency, sending the operating instruction of the heat dissipation fan to the heat dissipation fan of the cooling tower, where the operating instruction instructs the heat dissipation fan to operate according to the operating frequency in the operating instruction.

Furthermore, the operating frequency can refer to a number of rotations of the heat dissipation fan per unit time period. For example, the operating frequency is 5 times/second. Of course, in practical applications, a maximum operating frequency and a minimum operating frequency of the heat dissipation fan can be set. The maximum operating frequency can refer to a maximum number of rotation times of the heat dissipation fan per unit time period. The minimum operating frequency can refer to a minimum number of rotation times of the heat dissipation fan per unit time period. The values of maximum and minimum rotation times can be set according to usage requirements, and this is not limited too much in this embodiment.

In a technical solution of an embodiment of the present disclosure, a bypass valve of the wet-cooling heat dissipation system can be opened to start a liquid supply of the wet-cooling heat dissipation system when the cooling tower is turned on. In addition, in a case where it is detected that a liquid supply temperature of the wet-cooling heat dissipation system is greater than a preset second temperature threshold, controlling the dry-cooling heat dissipation system to operate, that is, during the initial start-up of the cooling tower, supplying liquid to the wet-cooling heat dissipation system, but does not activate the spraying of the wet-cooling heat dissipation system. As time goes by; the liquid supply temperature in the wet-cooling heat dissipation system continues to rise, it indicates that the temperature inside the cooling tower is constantly increasing. Therefore, when the liquid supply temperature is greater than the second temperature threshold, the dry-cooling heat dissipation system can be started, and the operating frequency of the heat dissipation fan of the dry-cooling heat dissipation system can be controlled through the PID adjustment algorithm. When the cooling tower is turned on, the dry-cooling heat dissipation system is not directly started, instead, the dry-cooling heat dissipation system is started when the liquid supply temperature is high, avoiding starting the dry-cooling heat dissipation system when cooling is not required, and improving the cooling effect.

As shown in FIG. 7, it is a flowchart of another embodiment of a heat dissipation control method based on a cooling tower provided in an embodiment of the present disclosure, the difference from the previous embodiment is that it further includes:

Step 701, detecting a number of mode switching times between the dry-cooling heat dissipation mode and the wet-cooling heat dissipation mode during a target time period.

In an implementation, the target time period can refer to a set duration, such as 1 hour. When switching from the dry-cooling heat dissipation mode to the wet-cooling heat dissipation mode, it can be determined that the number of mode switching times increases by 1. When switching from the wet-cooling heat dissipation mode to the dry-cooling heat dissipation mode, it can be determined that the number of mode switching times increases by 1.

Furthermore, during the operation of the cooling tower, a switching node from the dry-cooling heat dissipation mode to the wet-cooling heat dissipation mode and a switching node from the wet-cooling heat dissipation mode to the dry-cooling heat dissipation mode can be recorded. Each switching node can be associated with a switching time. It is possible to determine the number of switching nodes whose switching time is within the target time period, so as to determine the number of switching nodes as the number of mode switching times between the dry-cooling heat dissipation mode and the wet-cooling heat dissipation mode within the target time period.

Step 702, if it is determined that the number of mode switching times is greater than a preset number threshold, controlling the heat dissipation fan of the dry-cooling heat dissipation system to operate at a lowest frequency in a case of controlling the wet-cooling heat dissipation system to operate.

In an implementation, the number threshold is a pre-set number of mode switching times. The controlling the heat dissipation fan of the dry-cooling heat dissipation system to operate at the lowest frequency can include: generating the operating instruction according to the minimum operating frequency, that is, the minimum operating frequency, of the heat dissipation fan, and sending the operating instruction to the cooling tower, where the operation instruction indicates the heat dissipation fan of the cooling tower to operate at a lowest frequency. Specifically, it can refer to a microcontroller of the heat dissipation fan of the cooling tower, the heat dissipation fan is controlled by the microcontroller to operate at the lowest frequency.

In the technical solution of the present disclosure, if the number of mode switching times between the dry-cooling heat dissipation mode and the wet-cooling heat dissipation mode during the target time period is greater than the preset number threshold, the cooling tower frequently switch between the dry-cooling and wet-cooling modes. At this time, the operating mode of the cooling tower is not stable enough. Therefore, the wet-cooling heat dissipation mode can be activated and the heat dissipation fan of the dry-cooling heat dissipation system can be controlled to operate at the lowest frequency, thereby avoiding frequent switching between the dry-cooling and wet-cooling heat dissipation modes, and improving the operating stability of the cooling tower.

Further, on the basic of any one of the embodiments described above, after the controlling the heat dissipation fan of the dry-cooling heat dissipation system to operate at the lowest frequency in the case of controlling the wet-cooling heat dissipation system to operate, the method further includes:
collecting a liquid supply temperature in the wet-cooling heat dissipation system under the wet-cooling heat dissipation mode;
if it is detected that the liquid supply temperature is less than a preset second temperature threshold, turning off the wet-cooling heat dissipation mode, and controlling the heat dissipation fan of the dry-cooling heat dissipation system to operate at a maximum frequency.

Partial content of this embodiment is the same as partial content of the preceding embodiments, which can be described with reference to the above embodiments, and will not be repeated herein.

In the technical solution of the present disclosure, the liquid supply temperature of the wet-cooling heat dissipation system in the wet-cooling heat dissipation mode is collected, and when the liquid supply temperature is less than the second temperature threshold, the wet-cooling heat dissipation mode is turned off, and the heat dissipation fan of the wet-cooling heat dissipation system is controlled to operate at the maximum frequency. Thus, when the liquid supply temperature is low; switching to the dry-cooling heat dissipation, avoiding unnecessary wet-cooling heat dissipation, and improving the operating efficiency of the cooling tower.

Further, on the basic of any one of the embodiments described above, after the controlling the heat dissipation fan of the dry-cooling heat dissipation system to operate at the maximum frequency, the method further includes:
collecting a liquid supply temperature in the wet-cooling heat dissipation system;
if it is detected that the liquid supply temperature is greater than a preset fifth temperature threshold, controlling the heat dissipation fan of the dry-cooling heat dissipation system to operate at the lowest frequency in the case of controlling the wet-cooling heat dissipation system to operate.

In an implementation, the fifth temperature threshold can be set according to a usage requirement. For example, the fifth temperature threshold can be set to 35 degrees Celsius.

The collecting the liquid supply temperature in the wet-cooling heat dissipation system can include: collecting the liquid supply temperature in the wet-cooling heat dissipation system according to a wet-cooling collection frequency. Further, the wet-cooling collection frequency can be set according to a usage requirement.

In the technical solution of the present disclosure, when the liquid supply temperature in the wet-cooling heat dissipation system is greater than the fifth temperature threshold, it indicates that even if the dry-cooling heat dissipation system operates at the maximum frequency, the liquid supply temperature in the cooling tower is still high, and the dry-cooling heat dissipation mode can no longer meet the cooling requirements. Therefore, it is necessary to start the wet-cooling heat dissipation system and control the heat dissipation fan of the dry-cooling heat dissipation system to operate at the lowest frequency, ensuring that the cooling tower can meet the cooling requirements, and improving the cooling effect of the cooling tower.

Further, after the controlling the heat dissipation fan of the dry-cooling heat dissipation system to operate at the lowest frequency in a case of controlling the wet-cooling heat dissipation system to operate, the method further includes:
if it is detected that an opening degree of a bypass valve of the wet-cooling heat dissipation system is less than a preset first opening degree threshold, calculating a target opening degree of the bypass valve through a PID adjustment algorithm, and controlling the bypass valve to supply fluid in accordance with the target opening degree;
if it is detected that an opening degree of a bypass valve of the wet-cooling heat dissipation system is greater than a preset second opening degree threshold, closing the bypass valve to turn off the wet-cooling heat dissipation system, controlling the dry-cooling heat dissipation system to operate, and controlling an operating frequency of the heat dissipation fan of the dry-cooling heat dissipation system through the PID adjustment algorithm.

In an implementation, the opening degree of the bypass valve can refer to a ratio of a real-time liquid input speed of the heat dissipation coil to a maximum input speed of the heat dissipation coil under the control of the bypass valve. The larger the opening degree, the higher the input flow rate of the cooling liquid in the heat dissipation coil, and the smaller the opening degree, the lower the input flow rate of the cooling liquid in the heat dissipation coil.

The target opening degree of the bypass valve can be calculated through the PID adjustment algorithm, so as to control the bypass valve to control the flow rate of the cooling liquid using the target opening degree. For example, when the opening degree of the bypass valve is 30%, the target opening of the bypass valve can be obtained through calculating a product of the maximum opening degree of the bypass valve and 0.3. Of course, in practical applications, the target opening degree can be issued to the bypass valve in the form of an instruction, and the instruction can instruct the bypass valve to adjust to the target opening degree.

The first opening degree threshold can be less than the second opening degree threshold. The values of the first opening degree threshold and the second opening degree threshold can be set according to a usage requirement. For example, the first opening degree threshold can be set to 30%, and the second opening degree threshold can be set to 30%.

Partial content of this embodiment is the same as partial content of the above-mentioned embodiments, and will not be repeated herein.

In the technical solution of the present disclosure, when the opening degree of the bypass valve is less than the preset first opening degree threshold, the target opening degree of the bypass valve is calculated through the PID adjustment algorithm; and then, when the opening degree of the bypass valve is small, achieving automatic adjustment and control of the bypass valve using the PID adjustment algorithm, and realizing intelligent wet-cooling heat dissipation control. When it is detected that the opening degree of the bypass valve of the wet-cooling heat dissipation system is greater than the preset second opening degree threshold, closing the bypass valve to turn off the wet-cooling heat dissipation system, controlling the dry-cooling heat dissipation system to operate, and controlling the operating frequency of the heat dissipation fan of the dry-cooling heat dissipation system through a PID adjustment algorithm, which achieves automatic adjustment of the heat dissipation fan under the dry-cooling heat dissipation system. Through the PID adjustment algorithm, achieving a real-time adjustment of the control effect of the cooling system of the cooling tower, making the cooling effect of the cooling tower more matched with the actual cooling requirement, and improving the operating efficiency of the cooling tower.

As shown in FIG. 8, it is a schematic structural diagram of an embodiment of a heat dissipation control apparatus based on a cooling tower provided in an embodiment of the present disclosure. The cooling tower includes a dry-cooling heat dissipation system and a wet-cooling heat dissipation system, and the apparatus includes:
an information collection unit 801, configured to collect target heat dissipation information of the cooling tower in response to a heat dissipation control request of the cooling tower;
a dry-cooling heat dissipation unit 802, configured to, if it is detected that the target heat dissipation information meets a dry-cooling heat dissipation requirement, control the dry-cooling heat dissipation system to operate, so as to adopt a dry-cooling heat dissipation mode for heat dissipation;
a wet-cooling heat dissipation unit 803, configured to, if it is detected that the target heat dissipation information meets a wet-cooling heat dissipation requirement, control the wet-cooling heat dissipation system to operate, so as to adopt a wet-cooling heat dissipation mode for heat dissipation;
a joint heat dissipation unit 804, if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

As an embodiment, the dry-cooling heat dissipation unit includes:
a first detection module, configured to, in a case where the target heat dissipation information includes an ambient temperature outside a tower, if it is detected that the ambient temperature outside the tower is less than a preset first temperature threshold, determine that the target heat dissipation information meets the dry-cooling heat dissipation requirement; or
a second detection module, configured to, in a case where the target heat dissipation information includes a liquid supply temperature, if it is detected that the liquid supply temperature is less than a preset second temperature threshold, determine that the target heat dissipation information meets the dry-cooling heat dissipation requirement, where the liquid supply temperature refers to a temperature of liquid input to a heat dissipation coil of the wet-cooling heat dissipation system; or
a third detection module, configured to, in a case where the target heat dissipation information includes a water collecting tray temperature, if it is detected that the water collecting tray temperature is greater than a second temperature threshold, determine that the target heat dissipation information meets the dry-cooling heat dissipation requirement, where the water collecting tray temperature refers to a temperature of liquid in a water collecting tray of the wet-cooling heat dissipation system; or
a fourth detection module, configured to, in a case where the target heat dissipation information includes a liquid supply temperature, calculate a temperature difference obtained by subtracting a preset target temperature from the liquid supply temperature, if the temperature difference is greater than a preset temperature difference threshold, determine that the target heat dissipation information meets the dry-cooling heat dissipation requirement; or
a fifth detection module, configured to, in a case where the target heat dissipation information includes a liquid height, if it is detected that the liquid height is less than a preset height threshold, determine that the target heat dissipation information meets the dry-cooling heat dissipation requirement, where the liquid height indicates a height of liquid in a water collecting tray of the wet-cooling heat dissipation system.

As an embodiment, the dry-cooling heat dissipation unit includes:
a sixth detection module, configured to, in a case where the target heat dissipation information includes a liquid height, an ambient temperature outside a tower and a liquid supply temperature, and in a case where the liquid height is greater than or equal to a preset height threshold, if it is detected that the ambient temperature outside the tower is greater than a preset third temperature threshold, and the liquid supply temperature is greater than a fourth temperature threshold, determine that the target heat dissipation information meets the wet-cooling heat dissipation requirement; or
a seventh detection module, configured to, in a case where the target heat dissipation information includes a liquid height and an ambient temperature outside a tower, if it is detected that the liquid height is greater than or equal to a preset height threshold, and the ambient temperature outside the tower is less than a preset first temperature threshold, determine that the target heat dissipation information meets the dry-cooling heat dissipation requirement; or
an eighth detection module, configured to, in a case where the target heat dissipation information includes a liquid height and a water collecting tray temperature, if it is detected that the liquid height is greater than or equal to a preset height threshold, and the water collecting tray temperature is less than a preset first temperature threshold, determine that the target heat dissipation information meets the dry-cooling heat dissipation requirement.

As another embodiment, the information collection unit includes:
a strategy collection module, configured to collect at least one of an ambient temperature outside a tower, a liquid supply temperature inside the tower, a water collecting tray temperature, and a liquid height of the cooling tower in accordance with a preset parameter collection strategy;
an information determination module, configured to determine at least one of the ambient temperature outside the tower, the liquid supply temperature, the water collecting tray temperature, and the liquid height as the target heat dissipation information.

As another embodiment, further including:
a liquid supply start unit, configured to open a bypass valve of the wet-cooling heat dissipation system to start a liquid supply of the wet-cooling heat dissipation system when the cooling tower is turned on;
an adjustment control unit, configured to, if it is detected that a liquid supply temperature of the wet-cooling heat dissipation system is greater than a preset second temperature threshold, control the dry-cooling heat dissipation system to operate, and controlling an operating frequency of a heat dissipation fan of the dry-cooling heat dissipation system through a PID adjustment algorithm.

As another embodiment, further including:
a switch detection unit, configured to detect a number of mode switching times between the dry-cooling heat dissipation mode and the wet-cooling heat dissipation mode during a target time period;
a wet-cooling start unit, configured to, if it is determined that the number of mode switching times is greater than a preset number threshold, control a heat dissipation fan of the dry-cooling heat dissipation system to operate at a lowest frequency in a case of controlling the wet-cooling heat dissipation system to operate.

As another embodiment, further including:
a liquid supply collection unit, configured to collect a liquid supply temperature in the wet-cooling heat dissipation system under the wet-cooling heat dissipation mode;
a joint control unit, configured to, if it is detected that the liquid supply temperature is less than a preset second temperature threshold, turn off the wet-cooling heat dissipation mode, and control the heat dissipation fan of the dry-cooling heat dissipation system to operate at a maximum frequency.

As another embodiment,
the wet-cooling start unit is further configured to, if it is detected that the liquid supply temperature is greater than a preset fifth temperature threshold, control the heat dissipation fan of the dry-cooling heat dissipation system to operate at a lowest frequency in a case of controlling the wet-cooling heat dissipation system to operate.

As another embodiment, further including:
a bypass control unit, configured to, if it is detected that an opening degree of a bypass valve of the wet-cooling heat dissipation system is less than a preset first opening degree threshold, calculate a target opening degree of the bypass valve through a PID adjustment algorithm, and control the bypass valve to supply fluid in accordance with the target opening degree;
the adjustment control unit is further configured to, if it is detected that an opening degree of a bypass valve of the wet-cooling heat dissipation system is greater than a preset second opening degree threshold, close the bypass valve to turn off the wet-cooling heat dissipation system, control the dry-cooling heat dissipation system to operate, and control an operating frequency of the heat dissipation fan of the dry-cooling heat dissipation system through a PID adjustment algorithm.

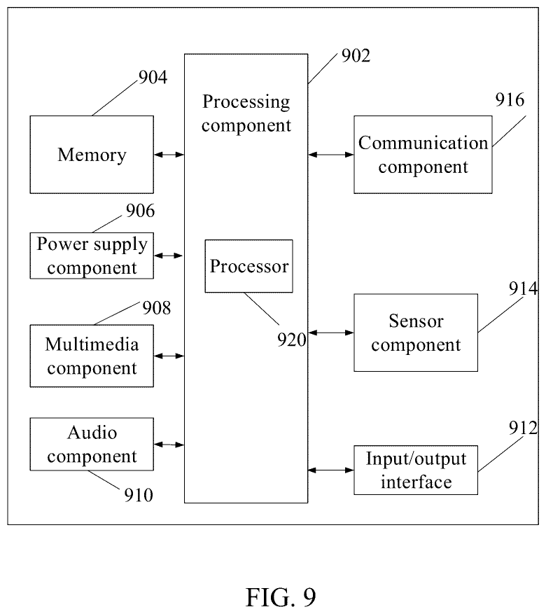

FIG. 9 is a block diagram of an electronic device according to an exemplary embodiment, the device may be a mobile phone, a computer, a digital broadcast terminal, a message transceiver, a game console, a tablet device, a medical device, a fitness device, a personal digital assistant, etc.

The device 900 may include one or more of the following components; a processing component 902, a memory 904, a power supply component 906, a multimedia component 908, an audio component 910, an input/output (I/O) interface 912, a sensor component 914, and a communication component 916.

The processing component 902 generally controls the overall operation of the apparatus 900, such as operations associated with display, phone calls, data communication, camera operations, and recording operations. The processing component 902 may include one or more processors 920 to execute instructions to complete all or part of the steps of the method described above. In addition, the processing component 902 may include one or more modules to facilitate interaction between the processing component 902 and other components. For example, the processing component 902 may include a multimedia module to facilitate interaction between the multimedia component 908 and the processing component 902.

The memory 904 is configured to store various types of data to support operations on the apparatus 900. Examples of such data include instructions, contact data, phonebook data, messages, images, videos, etc., of any application or method used to operate on the apparatus 900. The memory 904 can be implemented by any type of volatile or non-volatile storage device or combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic or optical disk.

The power supply component 906 provides power to various components of the apparatus 900. The power supply component 906 may include a power management system, one or more power supplies, and other components associated with generating, managing, and distributing power for the apparatus 900.

The multimedia component 908 includes a screen that provides an output interface between the apparatus 900 and the user. In some embodiments, the screen may include a liquid crystal display (LCD) and a touch panel (TP). If the screen includes a touch panel, the screen can be implemented as a touch screen to receive an input signal from the user. The touch panel includes one or more touch sensors to sense touches, sliding, and gestures on the touch panel. The touch sensor can not only sense the boundary of the touch or the slide action, but also detect the duration and pressure associated with the touch or the slide operation. In some embodiments, the multimedia component 908 includes a front camera and/or a rear camera. When the apparatus 900 is in an operating mode, such as a shooting mode or a video mode, the front camera and/or rear camera can receive external multimedia data. Each front camera and rear camera may be a fixed optical lens system or have a focal length and optical zoom capability.

The audio component 910 is configured to output and/or input audio signals. For example, the audio component 910 includes a microphone (MIC). When the apparatus 900 is in an operating mode, such as a call mode, a recording mode, and a voice recognition mode, the microphone is configured to receive an external audio signal. The received audio signal may be further stored in the memory 904 or sent via the communication component 916. In some embodiments, the audio component 910 further includes a speaker used to output an audio signal.

The I/O interface 912 provides an interface between the processing component 902 and a peripheral interface module, the peripheral interface module may be a keyboard, a click wheel, a button, etc. Such button may include, but is not limited to: a home button, a volume button, a start button, and a lock button.

The sensor component 914 includes one or more sensors used to provide a state evaluation of various aspects for the apparatus 900. For example, the sensor component 914 can detect an open/closed state of the apparatus 900, and the relative positioning of a component, for example, the component is a display and a keypad of the apparatus 900; the sensor component 914 can also detect a position change of the apparatus 900 or a component of the apparatus 900, the presence or absence of user contact with the apparatus 900, an orientation or acceleration/deceleration of the apparatus 900, and a temperature change of the apparatus 900. The sensor component 914 can include a proximity sensor configured to detect a presence of nearby objects without any physical contact. The sensor component 914 can also include a light sensor, such as a CMOS or a CCD image sensor, for use in an imaging application. In some embodiments, the sensor component 914 may also include an acceleration sensor, a gyroscope sensor, a magnetic sensor, a pressure sensor, or a temperature sensor.

The communication component 916 is configured to facilitate wired or wireless communication between the apparatus 900 and other devices. The apparatus 900 can access a wireless network based on communication standards, such as Wi-Fi, 2G or 3G, or a combination thereof. In an exemplary embodiment, the communication component 916 receives broadcast signals or broadcast related information from an external broadcast management system via a broadcast channel. In an exemplary embodiment, the communication component 916 further includes a near field communication (NFC) module to facilitate short-range communication. For example, the NFC module can be implemented based on a radio frequency identification (RFID) technology, an infrared data association (IrDA) technology, an ultra-wideband (UWB) technology, a Bluetooth (BT) technology, and other technologies.

In an exemplary embodiment, the apparatus 900 may be implemented by one or more application specific integrated circuits (ASICs), digital signal processors (DSPs), digital signal processing devices (DSPDs), programmable logic devices (PLDs), field programmable gate arrays (FPGAs), controllers, microcontrollers, microprocessors, or other electronic elements for executing the methods described above.

In an exemplary embodiment, a non-transitory computer-readable storage medium including instructions is also provided, such as the memory 904 including instructions, the instructions can be executable by the processor 920 of the apparatus 900 to accomplish the method described above. For example, the non-transitory computer-readable storage medium can include a ROM, a random access memory (RAM), a CD-ROM, a magnetic tape, a floppy disk, and an optical data storage device.

In addition, the present application also provides a computer-readable storage medium, storing computer execution instructions which, when executed by a processor, are used to implement the heat dissipation control method based on the cooling tower.

The present application also provides a computer program product, including a computer program which, when executed by a processor, implements the heat dissipation control method based on the cooling tower.

Those skilled in the art will easily come up with other embodiments of the present application after considering the specification and practicing the invention disclosed herein. The present application is intended to cover any variations, uses, or adaptive changes of the present application, and these variations, uses, or adaptive changes follow the general principles of the present application and include common knowledge or customary technical means in the technical field that are not disclosed in the present application. The specification and embodiments are only considered exemplary, and the true scope and spirit of the present application are indicated by the following claims.

It should be understood that the present application is not limited to the precise structure described above and shown in the accompanying drawings, and various modifications and changes can be made without departing from its scope. The scope of the present application is limited only by the appended claims.

1. A heat dissipation control method based on a cooling tower, wherein the cooling tower comprises a wet-cooling heat dissipation system and a dry-cooling heat dissipation system; and the method comprises:
in response to a heat dissipation control request, obtaining a cooling tower identifier in the heat dissipation control request, and collecting target heat dissipation information of a cooling tower corresponding to the cooling tower identifier;
if it is detected that the target heat dissipation information meets a dry-cooling heat dissipation requirement, controlling the dry-cooling heat dissipation system to operate, so as to adopt a dry-cooling heat dissipation mode for heat dissipation;
if it is detected that the target heat dissipation information meets a wet-cooling heat dissipation requirement, controlling the wet-cooling heat dissipation system to operate, so as to adopt a wet-cooling heat dissipation mode for heat dissipation;
if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

2. The method according to claim 1, wherein the detecting that the target heat dissipation information meets the dry-cooling heat dissipation requirement comprises:
in a case where the target heat dissipation information comprises an ambient temperature outside a tower, if it is detected that the ambient temperature outside the tower is less than a preset first temperature threshold, determining that the target heat dissipation information meets the dry-cooling heat dissipation requirement; or
in a case where the target heat dissipation information comprises a liquid supply temperature, if it is detected that the liquid supply temperature is less than a preset second temperature threshold, determining that the target heat dissipation information meets the dry-cooling heat dissipation requirement, wherein the liquid supply temperature refers to a temperature of liquid input to a heat dissipation coil of the wet-cooling heat dissipation system; or
in a case where the target heat dissipation information comprises a water collecting tray temperature, if it is detected that the water collecting tray temperature is greater than a second temperature threshold, determining that the target heat dissipation information meets the dry-cooling heat dissipation requirement, wherein the water collecting tray temperature refers to a temperature of liquid in a water collecting tray of the wet-cooling heat dissipation system; or
in a case where the target heat dissipation information comprises a liquid supply temperature, calculating a temperature difference obtained by subtracting a preset target temperature from the liquid supply temperature, if it is detected that the temperature difference is greater than a preset temperature difference threshold, determining that the target heat dissipation information meets the dry-cooling heat dissipation requirement; or
in a case where the target heat dissipation information comprises a liquid height, if it is detected that the liquid height is less than a preset height threshold, determining that the target heat dissipation information meets the dry-cooling heat dissipation requirement, wherein the liquid height indicates a height of liquid in a water collecting tray of the wet-cooling heat dissipation system.

3. The method according to claim 1, wherein the detecting that the target heat dissipation information meets the wet-cooling heat dissipation requirement comprises:
in a case where the target heat dissipation information comprises a liquid height, an ambient temperature outside a tower and a liquid supply temperature, and in a case where the liquid height is greater than or equal to a preset height threshold, if it is detected that the ambient temperature outside the tower is greater than a preset third temperature threshold, and the liquid supply temperature is greater than a fourth temperature threshold, determining that the target heat dissipation information meets the wet-cooling heat dissipation requirement; or
in a case where the target heat dissipation information comprises a liquid height and an ambient temperature outside a tower, if it is detected that the liquid height is greater than or equal to a preset height threshold, and the ambient temperature outside the tower is less than a preset first temperature threshold, determining that the target heat dissipation information meets the dry-cooling heat dissipation requirement; or
in a case where the target heat dissipation information comprises a liquid height and a water collecting tray temperature, if it is detected that the liquid height is greater than or equal to a preset height threshold, and the water collecting tray temperature is less than a preset first temperature threshold, determining that the target heat dissipation information meets the dry-cooling heat dissipation requirement.

4. The method according to claim 1, wherein the collecting the target heat dissipation information of the cooling tower corresponding to the cooling tower identifier comprises:
collecting at least one of an ambient temperature outside a tower, a liquid supply temperature inside the tower, a water collecting tray temperature, and a liquid height of the cooling tower in accordance with a preset parameter collection strategy;
determining at least one of the ambient temperature outside the tower, the liquid supply temperature, the water collecting tray temperature, and the liquid height as the target heat dissipation information.

5. The method according to claim 1, further comprising:
opening a bypass valve of the wet-cooling heat dissipation system to start a liquid supply of the wet-cooling heat dissipation system when the cooling tower is turned on;
if it is detected that a liquid supply temperature of the wet-cooling heat dissipation system is greater than a preset second temperature threshold, controlling the dry-cooling heat dissipation system to operate, and controlling an operating frequency of a heat dissipation fan of the dry-cooling heat dissipation system through a Proportional-Integral-Derivative (PID) adjustment algorithm.

6. The method according to claim 1, further comprising:
detecting a number of mode switching times between the dry-cooling heat dissipation mode and the wet-cooling heat dissipation mode during a target time period;
if it is determined that the number of mode switching times is greater than a preset number threshold, controlling a heat dissipation fan of the dry-cooling heat dissipation system to operate at a lowest frequency in a case of controlling the wet-cooling heat dissipation system to operate.

7. The method according to claim 6, wherein after the controlling the heat dissipation fan of the dry-cooling heat dissipation system to operate at the lowest frequency in the case of controlling the wet-cooling heat dissipation system to operate, the method further comprises:
collecting a liquid supply temperature in the wet-cooling heat dissipation system under the wet-cooling heat dissipation mode;
if it is detected that the liquid supply temperature is less than a preset second temperature threshold, turning off the wet-cooling heat dissipation mode, and controlling the heat dissipation fan of the dry-cooling heat dissipation system to operate at a maximum frequency.

8. The method according to claim 7, wherein after the controlling the heat dissipation fan of the dry-cooling heat dissipation system to operate at the maximum frequency, the method further comprises:
if it is detected that the liquid supply temperature is greater than a preset fifth temperature threshold, controlling the heat dissipation fan of the dry-cooling heat dissipation system to operate at the lowest frequency in the case of controlling the wet-cooling heat dissipation system to operate.

9. The method according to claim 6, wherein after the controlling the heat dissipation fan of the dry-cooling heat dissipation system to operate at the lowest frequency in the case of controlling operation of the wet-cooling heat dissipation system, the method further comprises:
if it is detected that an opening degree of a bypass valve of the wet-cooling heat dissipation system is less than a preset first opening degree threshold, calculating a target opening degree of the bypass valve through a PID adjustment algorithm, and controlling the bypass valve to supply fluid in accordance with the target opening degree;
if it is detected that an opening degree of a bypass valve of the wet-cooling heat dissipation system is greater than a preset second opening degree threshold, closing the bypass valve to turn off the wet-cooling heat dissipation system, controlling the dry-cooling heat dissipation system to operate, and controlling an operating frequency of the heat dissipation fan of the dry-cooling heat dissipation system through the PID adjustment algorithm.

10. A heat dissipation control apparatus based on a cooling tower, wherein the cooling tower comprises a wet-cooling heat dissipation system and a dry-cooling heat dissipation system; and the apparatus comprises: a processor, and a memory connected in communication with the processor;
wherein the memory stores computer execution instructions;
the processor executes the computer execution instructions stored in the memory to implement the following steps:
collecting target heat dissipation information of the cooling tower in response to a heat dissipation control request of the cooling tower;
if it is detected that the target heat dissipation information meets a dry-cooling heat dissipation requirement, controlling the dry-cooling heat dissipation system to operate, so as to adopt a dry-cooling heat dissipation mode for heat dissipation;
if it is detected that the target heat dissipation information meets a wet-cooling heat dissipation requirement, controlling the wet-cooling heat dissipation system to operate, so as to adopt a wet-cooling heat dissipation mode for heat dissipation;
if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

11. (canceled)

12. The apparatus according to claim 10, wherein the processor is specifically configured to:
in a case where the target heat dissipation information comprises an ambient temperature outside a tower, if it is detected that the ambient temperature outside the tower is less than a preset first temperature threshold, determine that the target heat dissipation information meets the dry-cooling heat dissipation requirement; or
in a case where the target heat dissipation information comprises a liquid supply temperature, if it is detected that the liquid supply temperature is less than a preset second temperature threshold, determine that the target heat dissipation information meets the dry-cooling heat dissipation requirement, wherein the liquid supply temperature refers to a temperature of liquid input to a heat dissipation coil of the wet-cooling heat dissipation system; or
in a case where the target heat dissipation information comprises a water collecting tray temperature, if it is detected that the water collecting tray temperature is greater than a second temperature threshold, determine that the target heat dissipation information meets the dry-cooling heat dissipation requirement, wherein the water collecting tray temperature refers to a temperature of liquid in a water collecting tray of the wet-cooling heat dissipation system; or
in a case where the target heat dissipation information comprises a liquid supply temperature, calculate a temperature difference obtained by subtracting a preset target temperature from the liquid supply temperature, if it is detected that the temperature difference is greater than a preset temperature difference threshold, determine that the target heat dissipation information meets the dry-cooling heat dissipation requirement; or
in a case where the target heat dissipation information comprises a liquid height, if it is detected that the liquid height is less than a preset height threshold, determine that the target heat dissipation information meets the dry-cooling heat dissipation requirement, wherein the liquid height indicates a height of liquid in a water collecting tray of the wet-cooling heat dissipation system.

13. The apparatus according to claim 10, wherein the processor is specifically configured to:
in a case where the target heat dissipation information comprises a liquid height, an ambient temperature outside a tower and a liquid supply temperature, and in a case where the liquid height is greater than or equal to a preset height threshold, if it is detected that the ambient temperature outside the tower is greater than a preset third temperature threshold, and the liquid supply temperature is greater than a fourth temperature threshold, determine that the target heat dissipation information meets the wet-cooling heat dissipation requirement; or
in a case where the target heat dissipation information comprises a liquid height and an ambient temperature outside a tower, if it is detected that the liquid height is greater than or equal to a preset height threshold, and the ambient temperature outside the tower is less than a preset first temperature threshold, determine that the target heat dissipation information meets the dry-cooling heat dissipation requirement; or
in a case where the target heat dissipation information comprises a liquid height and a water collecting tray temperature, if it is detected that the liquid height is greater than or equal to a preset height threshold, and the water collecting tray temperature is less than a preset first temperature threshold, determine that the target heat dissipation information meets the dry-cooling heat dissipation requirement.

14. The apparatus according to claim 10, wherein the processor is specifically configured to:
collect at least one of an ambient temperature outside a tower, a liquid supply temperature inside the tower, a water collecting tray temperature, and a liquid height of the cooling tower in accordance with a preset parameter collection strategy;
determine at least one of the ambient temperature outside the tower, the liquid supply temperature, the water collecting tray temperature, and the liquid height as the target heat dissipation information.

15. The apparatus according to claim 10, wherein the processor is further configured to:
open a bypass valve of the wet-cooling heat dissipation system to start a liquid supply of the wet-cooling heat dissipation system when the cooling tower is turned on;
if it is detected that a liquid supply temperature of the wet-cooling heat dissipation system is greater than a preset second temperature threshold, control the dry-cooling heat dissipation system to operate, and control an operating frequency of a heat dissipation fan of the dry-cooling heat dissipation system through a Proportional-Integral-Derivative (PID) adjustment algorithm.

16. The apparatus according to claim 10, wherein the processor is further configured to:
detect a number of mode switching times between the dry-cooling heat dissipation mode and the wet-cooling heat dissipation mode during a target time period;
if it is determined that the number of mode switching times is greater than a preset number threshold, control a heat dissipation fan of the dry-cooling heat dissipation system to operate at a lowest frequency in a case of controlling the wet-cooling heat dissipation system to operate.

17. The apparatus according to claim 15, wherein after the controlling the heat dissipation fan of the dry-cooling heat dissipation system to operate at the lowest frequency in the case of controlling the wet-cooling heat dissipation system to operate, the processor is further configured to:
collect a liquid supply temperature in the wet-cooling heat dissipation system under the wet-cooling heat dissipation mode;
if it is detected that the liquid supply temperature is less than a preset second temperature threshold, turn off the wet-cooling heat dissipation mode, and control the heat dissipation fan of the dry-cooling heat dissipation system to operate at a maximum frequency.

18. The apparatus according to claim 16, wherein after the controlling the heat dissipation fan of the dry-cooling heat dissipation system to operate at the maximum frequency, the processor is further configured to:
if it is detected that the liquid supply temperature is greater than a preset fifth temperature threshold, control the heat dissipation fan of the dry-cooling heat dissipation system to operate at the lowest frequency in the case of controlling the wet-cooling heat dissipation system to operate.

19. The apparatus according to claim 15, wherein after the controlling the heat dissipation fan of the dry-cooling heat dissipation system to operate at the lowest frequency in the case of controlling operation of the wet-cooling heat dissipation system, the processor is further configured to:
if it is detected that an opening degree of a bypass valve of the wet-cooling heat dissipation system is less than a preset first opening degree threshold, calculate a target opening degree of the bypass valve through a PID adjustment algorithm, and control the bypass valve to supply fluid in accordance with the target opening degree;
if it is detected that an opening degree of a bypass valve of the wet-cooling heat dissipation system is greater than a preset second opening degree threshold, close the bypass valve to turn off the wet-cooling heat dissipation system, control the dry-cooling heat dissipation system to operate, and control an operating frequency of the heat dissipation fan of the dry-cooling heat dissipation system through the PID adjustment algorithm.

20. A non-transitory computer-readable storage medium, storing computer execution instructions which, when executed by a processor, are used to implement the following steps:
collecting target heat dissipation information of the cooling tower in response to a heat dissipation control request of the cooling tower;
if it is detected that the target heat dissipation information meets a dry-cooling heat dissipation requirement, controlling the dry-cooling heat dissipation system to operate, so as to adopt a dry-cooling heat dissipation mode for heat dissipation;
if it is detected that the target heat dissipation information meets a wet-cooling heat dissipation requirement, controlling the wet-cooling heat dissipation system to operate, so as to adopt a wet-cooling heat dissipation mode for heat dissipation;
if it is detected that the target heat dissipation information meets neither the dry-cooling heat dissipation requirement nor the wet-cooling heat dissipation requirement, controlling the wet-cooling heat dissipation system and the dry-cooling heat dissipation system to operate simultaneously, so as to adopt both the dry-cooling heat dissipation mode and the wet-cooling heat dissipation mode for heat dissipation.

21. The non-transitory computer-readable storage medium according to claim 19, wherein when the computer execution instructions are executed by the processor, the processor is specifically configured to:
in a case where the target heat dissipation information comprises an ambient temperature outside a tower, if it is detected that the ambient temperature outside the tower is less than a preset first temperature threshold, determine that the target heat dissipation information meets the dry-cooling heat dissipation requirement; or
in a case where the target heat dissipation information comprises a liquid supply temperature, if it is detected that the liquid supply temperature is less than a preset second temperature threshold, determine that the target heat dissipation information meets the dry-cooling heat dissipation requirement, wherein the liquid supply temperature refers to a temperature of liquid input to a heat dissipation coil of the wet-cooling heat dissipation system; or
in a case where the target heat dissipation information comprises a water collecting tray temperature, if it is detected that the water collecting tray temperature is greater than a second temperature threshold, determine that the target heat dissipation information meets the dry-cooling heat dissipation requirement, wherein the water collecting tray temperature refers to a temperature of liquid in a water collecting tray of the wet-cooling heat dissipation system; or
in a case where the target heat dissipation information comprises a liquid supply temperature, calculate a temperature difference obtained by subtracting a preset target temperature from the liquid supply temperature, if it is detected that the temperature difference is greater than a preset temperature difference threshold, determine that the target heat dissipation information meets the dry-cooling heat dissipation requirement; or
in a case where the target heat dissipation information comprises a liquid height, if it is detected that the liquid height is less than a preset height threshold, determine that the target heat dissipation information meets the dry-cooling heat dissipation requirement, wherein the liquid height indicates a height of liquid in a water collecting tray of the wet-cooling heat dissipation system.
